(19) United States
(12) Patent Application Publication
(10) Pub. No.: US 2025/0283920 A1
(43) Pub. Date: Sep. 11, 2025

(54) OPTICAL VOLTAGE SENSING SYSTEMS AND ELECTRO-OPTIC CRYSTAL ASSEMBLIES

(71) Applicant: Hubbell Incorporated, Shelton, CT (US)

(72) Inventors: James Norman Blake, Scottsdale, AZ (US); Calvin Russell Blake, Phoenix, AZ (US)

(21) Appl. No.: 19/073,242

(22) Filed: Mar. 7, 2025

Related U.S. Application Data
(60) Provisional application No. 63/562,459, filed on Mar. 7, 2024.

(51) Int. Cl. G01R 15/24; G01R 15/16; G01R 15/22; H04B 3/46; H04B 3/54

(52) U.S. Cl. CPC G01R 15/241; G01R 15/16; G01R 15/22; G01R 15/247; H04B 3/46; H04B 3/54

(57) ABSTRACT

An optical voltage sensor system for measuring a high-voltage (HV) signal includes a voltage divider configured to generate a low-voltage (LV) signal representative of the HV signal, an electro-optic crystal, and electrodes arranged on the electro-optic crystal and connected to receive the LV signal from the voltage divider. The electrodes are configured, upon an unpolarized light beam being launched through the electro-optic crystal, to apply a voltage of the LV signal to the electro-optic crystal to alter a spatial distribution of a portion of the light beam exiting the electro-optic crystal in response to the LV signal. The optical voltage sensor system further includes a light collector configured to collect light having an intensity which varies based on the applied voltage, and a light converter configured to convert the collected light into an electronic signal representative of the HV signal.

### CROSS-REFERENCE TO RELATED APPLICATIONS

The present application claims priority from, and incorporates by reference in its entirety, U.S. provisional patent application 63/562,459 filed Mar. 7, 2024.

### FIELD

The present disclosure relates to optical voltage sensing systems, and more particularly to optical voltage sensing systems using unpolarized light passing through an electro-optic crystal assembly.

### BACKGROUND

The ability to sense, measure and monitor voltage plays an important role in many industries. The ability to accurately measure and monitor voltage is particularly acute with electrical power systems. As will be appreciated, the extremely high voltages associated with electrical conductors in power lines presents unique challenges to power companies and the like to measure and monitor these voltages and the transmission of electricity through the power grid. Conventional voltage sensing in the electric power industry is typically performed in substations and the like using capacitive voltage transducer (CVT) technology. With CVTs, a high voltage (e.g., 69 kV or higher), is divided down to a lower voltage (e.g., 12 kV) by a capacitive divider. Then the 12 kV signal is further divided down to 120V by a voltage transformer. This 120V signal is then transferred by wire to the substation control room where it is used by secondary equipment (e.g., relays, recorders, or meters). As will be appreciated, these lower voltages do not present the potential for damage to equipment that are present with high voltages.

The present inventors recognized several drawbacks associated with conventional CVT technology. First, because the voltage information is transferred by wire over a long distance (typically >100 meters), the signal needs to be strong enough to avoid being corrupted by substation noise and electrical pickup. This typically requires that the capacitance in the voltage divider be relatively high—typically in the nano-Farads. To achieve such capacitance levels, oil or SF6 insulation is conventionally used. Both oil and SF6 can present safety and environmental risks.

Second, because 120V signals are transferred by wire across the substation yard, there remains a safety risk of electric shock. This risk is exacerbated by fault level voltages (e.g., lightning strikes) which can raise the voltage on these wires to several thousand volts temporarily.

Third, because the 120V signals are derived using capacitors and transformers, the electrical bandwidth of the device can have peaks and valleys. Ferro-resonance may have consequences in CVT technology. For example, it can cause faulted waveforms to be distorted, or to be otherwise unfaithfully represented at the secondary equipment. The present inventors recognized the benefits and advantages to be derived from a new means of voltage sensing that overcomes the drawbacks of conventional devices.

### SUMMARY

Various embodiments of the present disclosure can overcome several drawbacks associated with conventional CVT technology recognized by the present inventors and offer new advantages as well.

Various embodiments disclosed herein provide an optical voltage sensor system for measuring a high-voltage (HV) signal. In some configurations, the optical voltage sensor system includes a voltage divider configured to generate a low-voltage (LV) signal representative of the HV signal. The optical voltage sensor system also includes an electro-optic crystal and a plurality of electrodes arranged on the sides of the electro-optic crystal. The electro-optic crystal is connected to receive the LV signal from the voltage divider.

In these configurations, an unpolarized light beam is launched through the electro-optic crystal with the plurality of electrodes configured to apply a voltage of the LV signal along the sides of the electro-optic crystal. This arrangement alters the spatial distribution of a portion of the light beam exiting the electro-optic crystal in response to the LV signal. In some embodiments, a light collector configured to collect light having an intensity which varies based on the applied voltage, and a light converter configured to convert the collected light into an electronic signal representative of the HV signal are used.

The converted signal may then be communicated to other equipment in the substation. Such other equipment may include opto-electronics with digital signal processing, analog filtering, and/or transformer-based amplifier. The information derived may be used for typical substation voltage monitoring activities such as metering, monitoring, and communicating with safety equipment and other secondary equipment.

In certain embodiments, the voltage divider includes one or more passive resistors and one or more capacitors. In a preferred embodiment, the LV fed to the electro-optical crystal is 120V or below, preferably below 100V.

In certain embodiments, the electro-optic crystal includes Y-cut LiNbO3. The system may use an optical fiber for directing the unpolarized light beam to the electro-optic crystal. The optical fiber is typically embodied as a single-mode fiber. A depolarizer may be configured to create the unpolarized light by passing at least partially polarized light through the depolarizer in certain embodiments. In a preferred embodiment, the depolarizer is a Lyot depolarizer. In an alternative embodiment, the depolarizer is a polarization scrambler. In other embodiments, an unpolarized light launcher is used to launch the unpolarized light beam through the electro-optic crystal.

In certain embodiments, the plurality of electrodes are arranged on the electro-optic crystal so as to create a non-zero electric field gradient across a portion of the light beam propagating through the electro-optic crystal in response to the low-voltage signal.

In certain embodiments, the electrodes are strip electrodes. In some embodiments, the plurality of electrodes includes two positive electrodes arranged on opposite first and second sides of the electro-optic crystal, and two negative electrodes arranged on opposite third and fourth sides of the electro-optic crystal. In alternative embodiments, the plurality of electrodes includes two pairs of electrodes arranged on opposite first and second sides of the electro-optic crystal, each pair including a positive electrode and a negative electrode.

In certain embodiments, there is provided an electro-optic crystal assembly comprising an electro-optic crystal, and a plurality of electrodes arranged on the electro-optic crystal and configured, in response to an unpolarized light beam being launched through the electro-optic crystal and a low-voltage signal being received by the at least two electrodes, to apply a voltage of the low-voltage signal to the electro-optic crystal to alter a spatial distribution of a portion of the light beam exiting the electro-optic crystal in response to the low-voltage signal.

In some embodiments, the plurality of electrodes includes two positive electrodes arranged on opposite first and second sides of the electro-optic crystal, and two negative electrodes arranged on opposite third and fourth sides of the electro-optic crystal. In other embodiments, the plurality of electrodes includes two pairs of electrodes arranged on opposite first and second sides of the electro-optic crystal, each pair including a positive electrode and a negative electrode.

In some configurations, such as in a transmission substation, the system is configured to monitor all three phase conductors of the transmissions lines. In these configurations, the system may use separate voltage dividers associated with each separate phase conductor for outputting a LV. Each LV output from each voltage divider is connected to opto-electric crystal distributed in a multiplexor ladder so a single light source and collector may be used.

In a preferred embodiment, the multiplexor has a light source, a photodetector, a 2×5 coupler, three separate voltage transducers, a temperature line, and a reference line. Delay coils may be used to separate the five signals coming out of the 2×5 coupler and then communicated to a photodetector. With this configuration, the quality of the three phase conductors may be isolated from one another and monitored separately using the same light source and photodetector in the electro-optic crystal ladder array.

In certain embodiments, the electro-optic crystal assembly as described herein is used as part of substation monitoring system. According to some embodiments, the substation includes a voltage divider associated with each of the three phase conductors of the power transmission lines entering the substation.

Preferably, the systems uses a solid high voltage divider of the type described in described in commonly owned and co-pending U.S. Ser. No. 19/068,063, filed Mar. 3, 2025, based on U.S. Provisional Application No. 63/560,207 filed on Mar. 1, 2024, both entitled “High Voltage Solid Insulated Capacitive-Resistive Divider” to Dragan D. Tabakovic, the entire contents of both of which are hereby incorporated by reference.

In certain embodiments, the LV exiting the voltage divider(s) is arranged as part of a multiplexor ladder. In these embodiments, the multiplexor may use a single light source, a single detector, a 2×5 coupler, a light level reference and a temperature reference, and a series of delay coils for allowing the phase conductors to be monitored separately using the single light source and single detector. The output may then communicated via optical fiber for further monitoring and processing to the opto-electronics unit with digital signal processing capabilities, which in turn, feeds the signal to an analog filtering unit and transformer based voltage amplifier for use in secondary equipment, controls, monitors, and meters.

Preferably, the system uses three of the coupler output paths to communicate with a separate electro-optic crystal assembly associated with each of the three phase conductors. With this arrangement, each phase is monitored separately while allowing for the use of a single light source and a single detector as the delay coils will allow the outputs to remain separate when reaching the detector.

The disclosure herein should become evident to a person of ordinary skill in the art given the following enabling description and drawings. The drawings are for illustration purposes only and are not drawn to scale unless otherwise indicated. The drawings are not intended to limit the scope of the invention. The following enabling disclosure is directed to one of ordinary skill in the art and presupposes that those aspects within the ability of the ordinarily skilled artisan are understood and appreciated.

### BRIEF DESCRIPTION OF THE DRAWINGS

Various aspects and advantageous features of the present disclosure will become more apparent to those of ordinary skill when described in the detailed description of preferred embodiments and reference to the accompany drawing wherein:

FIG. 1 depicts a block diagram of an optical voltage sensing system in accordance with various embodiments.

FIG. 2 depicts a schematic representation of an electro-optic crystal assembly suitable for sensing voltage of a signal, in accordance with various embodiments.

FIG. 3 is an oblique view of a set of electrodes arranged on an electro-optic crystal in a first configuration in accordance with various embodiments.

FIG. 4 is an oblique view of a set of electrodes arranged on an electro-optic crystal in a second configuration in accordance with various embodiments.

FIG. 5 is an oblique view of a set of electrodes arranged on an electro-optic crystal in a third configuration in accordance with various embodiments.

FIG. 6 depicts a schematic representation of an optical voltage sensing device suitable for sensing multiple signals in accordance with various embodiments.

FIG. 7 depicts a partial block diagram of an optical voltage sensing system for use with a three-phase power system.

### DETAILED DESCRIPTION

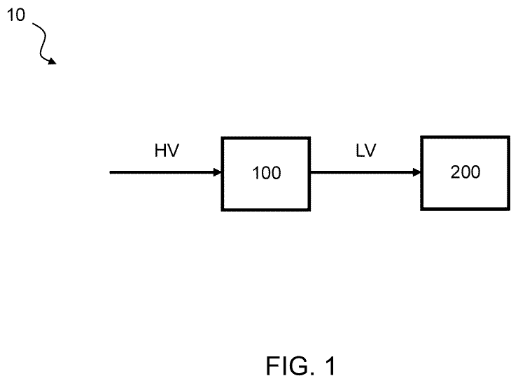

FIG. 1 depicts a block diagram of an optical voltage sensing system in accordance with various embodiments. In various embodiments an optical voltage sensor system 10 for measuring a high-voltage (HV) signal includes a voltage divider 100 and an electro-optic crystal assembly 200. The voltage divider 100 is configured to generate a low-voltage (LV) signal representative of the HV signal. The HV signal can be an alternating current (AC) signal.

In various embodiments, the LV signal typically ranges from 20 to 200 volts. Implementations of various embodiments may be adapted to operate with a higher or lower LV signal that the typical range. The HV signal typically ranges from 69 kV to 171 kV, but is not limited to this range. The HV signal often originates, for example, from an electrical power line configured for long distance transmission of electric power. Some countries around the world may use higher transport voltages than the typical range stated above. For example, in India the HV signal may be as high as 1.2 MV (1.2 million volts). Implementations of various embodiments may be adapted to operate with a higher (or lower) HV signal that the typical range.

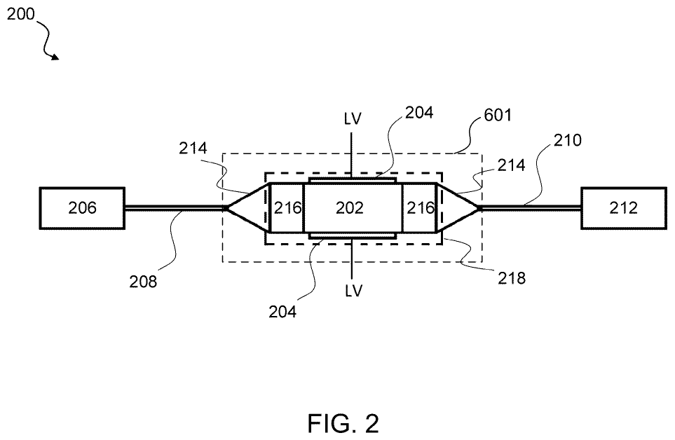

The voltage divider 100 can include a low-capacitance voltage divider, including, e.g., one or more passive resistors and one or more capacitors. Alternatively, the voltage divider 100 can include any other suitable voltage divider known in the art. The voltage divider 100 outputs the LV signal to the electro-optic crystal assembly 200, illustrated in more detail in FIG. 2.

FIG. 2 depicts a schematic representation of an electro-optic crystal assembly suitable for sensing voltage of a signal, in accordance with various embodiments. In various embodiments the electro-optic crystal assembly 200 includes an electro-optic crystal 202. The electro-optic crystal 202 can include, for example, a Y-cut LiNbO₃ crystal. Alternatively, a BGO or a BSO crystal may be used, or other type of crystal known to those of ordinary skill in the art.

In various embodiments the electro-optic crystal assembly 200 further includes a plurality of electrodes 204 arranged on the electro-optic crystal 202 and connected to receive the LV signal from a voltage divider such as voltage divider 100 of FIG. 1. The electrodes 204 are configured—in response to an unpolarized light beam being launched through the electro-optic crystal 202—to apply a voltage of the LV signal to the electro-optic crystal 202. This alters the spatial distribution of a portion of the light beam exiting the electro-optic crystal 202 in response to the LV signal.

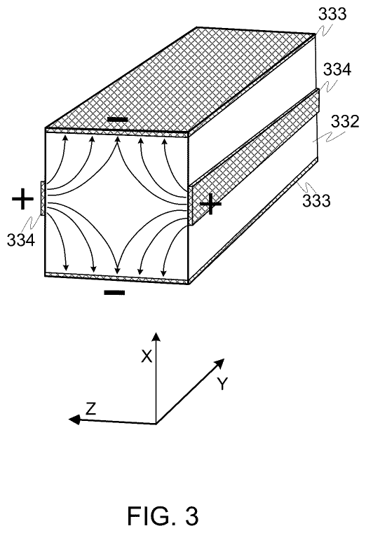

In various embodiments the electrodes 204 are arranged on the electro-optic crystal 202 so as to create a non-zero electric field gradient across a portion of the light beam propagating through the electro-optic crystal 202 in response to the LV signal. The electrodes 204 can be strip electrodes, for example, disposed along the main longitudinal direction of the electro-optic crystal 202, to advantageously control the electric field across the length of the electro-optic crystal 202. Various implementations of electrodes 204 arranged on electro-optic crystal 202 are illustrated in FIGS. 3-5.

FIG. 3 is an oblique view of a set of electrodes arranged on an electro-optic crystal 332 in a first configuration in accordance with various embodiments. In various embodiments the plurality of electrodes 333/334 include two positive electrodes 334 arranged on opposite first and second sides of the electro-optic crystal 332, and two negative electrodes 333 arranged on opposite third and fourth sides of the electro-optic crystal 332. To clarify the explanation, the surfaces of electro-optic crystal 332 that the electrodes 333/334 are mounted on are referred to as “sides” of the crystal. The portions where light enters and exits the electro-optic crystal 332 are referred to as “ends”. The Y direction in FIG. 3, from end-to-end of the electro-optic crystal 332, is the longitudinal direction.

Arrows within the electro-optic crystal 332 of FIG. 3 represent the direction of the electric field. The light beam passing through the electro-optic crystal 332 in the +/−Y direction deflects transversely within the electro-optic crystal 332 due to the AC voltage of the LV signal applied to the four electrodes. The deflection is due to the electro-optic effect alternately adding and subtracting refractive index into the upper and lower portions of the electro-optic crystal 332, respectively.

As illustrated in FIG. 3, the negative electrodes 333 span the entire width of the electro-optic crystal 332, while the positive electrodes 334 span only a portion of the height of the electro-optic crystal 332. Alternatively, the positive and negative electrodes 334/333 can each span either a portion or the entire height/width of the sides of electro-optic crystal 332.

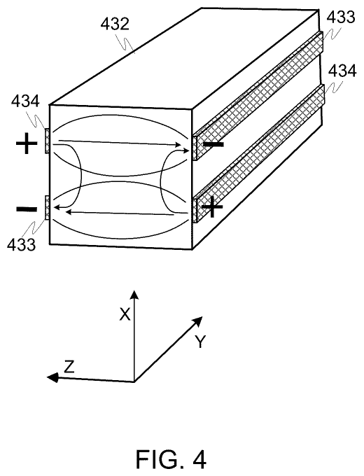

FIG. 4 is an oblique view of a set of electrodes arranged on an electro-optic crystal 432 in a second configuration in accordance with various embodiments. In various embodiments the plurality of electrodes 433/404 include two pairs of electrodes arranged on opposite first and second sides of the electro-optic crystal 432. Each pair includes a positive electrode 434 and a negative electrode 433. In the illustrated embodiment, the positive electrode 434 of the first pair faces the negative electrode 433 of the second pair, and the negative electrode 433 of the first pair faces the positive electrode 434 of the second pair.

Arrows within the electro-optic crystal 432 of FIG. 4 represent the direction of the electric field. The light beam passing through the electro-optic crystal 432 in the +/−Y direction deflects transversely within the electro-optic crystal 432 due to the AC voltage applied to the four electrodes. The deflection is due to the electro-optic effect alternately adding and subtracting refractive index into the upper and lower portions of the electro-optic crystal 432, respectively.

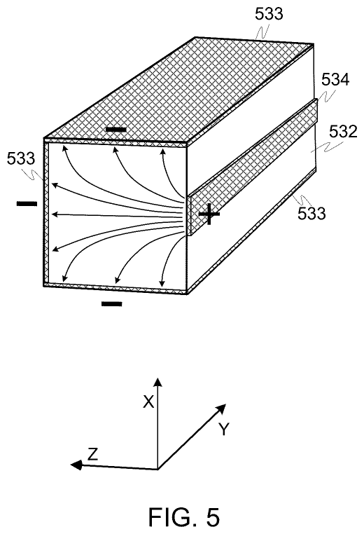

FIG. 5 is an oblique view of a set of electrodes arranged on an electro-optic crystal 532 in a third configuration in accordance with various embodiments. In various embodiments negative electrodes 533 are arranged to cover three sides, and a positive electrode 534 partially covers the fourth side of the electro-optic crystal 532.

Arrows within the electro-optic crystal 532 of FIG. 5 represent the direction of the electric field. The light beam passing through the electro-optic crystal 532 deflects somewhat between the positive and negative electrodes 534/533 due to the AC voltage applied to the electrodes. The deflection is due to the electro-optic effect alternately adding and subtracting refractive index of the electro-optic crystal 532, respectively.

Turning again to FIG. 2, in various embodiments the electro-optic crystal assembly 200 includes an unpolarized light launcher 206 configured to launch an unpolarized light beam through the electro-optic crystal 202. The unpolarized light launcher 202 can include a depolarizer configured to create the unpolarized light by passing at least partially polarized light through the depolarizer. The depolarizer can be, for example, a Lyot depolarizer, a polarization scrambler, or other such device for depolarizing light known to those of ordinary skill in the art.

In various embodiments the electro-optic crystal assembly 200 includes an optical fiber 208 for directing the unpolarized light beam from the unpolarized light launcher 206 to the electro-optic crystal 202. The unpolarized light launcher 206 may be implemented as a superluminescence diode (e.g., a 1.3 micron superluminescence diode), or other sources of unpolarized light known to those of ordinary skill in the art.

The optical fiber 208 can is typically embodied as a single-mode fiber. It would be possible to use a multi-mode fiber. However, single-mode fiber may be preferable since there are readily available components for use with single-mode fiber (e.g., 2×5 couplers), single-mode fiber generally attenuates the signal less than multi-mode, and single-mode fiber tends to be more affordable than multi-mode fiber.

In various embodiments the electro-optic crystal assembly 200 includes strain relief bushings 214, for example, for mechanical support at the end of the optical fiber 208 and the light collector 210. That is, the strain relief bushings 214 can help protect connected components of the electro-optic crystal assembly 200 against physical stress. The electro-optic crystal assembly 200 typically includes a light collector 210 which may be connected to the strain relief bushings 214.

In various embodiments the light collector 210 is configured to collect, from the electro-optic crystal 202, light having an intensity which varies based on the applied voltage. The light collector 210 can be a spatially sensitive light collector, such as an optical fiber, which can include, for example, a single-mode fiber or a multi-mode fiber. As explained above, a single-mode fiber may be preferable to minimize signal attenuation, while a multi-mode fiber tend to be less costly. The light collector 210 may be referred to as fiber optic cable 210.

In various embodiments the electro-optic crystal assembly 200 includes a light converter 212 (or photodetector) configured to convert the collected light, which is a facsimile of the HV signal, into an electrical or electronic signal representative of the HV signal. The light converter 212 may be embodied as a PIN diode, or other types of light converters known to those of ordinary skill in the art.

In some embodiments the components of electro-optic crystal assembly 200 before the fiber optic cable 210 may be positioned proximate the voltage divider which is near the high voltage electrical line at an electrical substation. The fiber optic cable 210 may extend from the electro-optic crystal assembly 200 across the yard of the substation to the control room (or control unit) where the light converter 212 is located. Using the fiber optic cable 210 to carry the facsimile of the HV signal across the substation yard eliminates the need to run a LV line (e.g., 120V) across the yard, thus improving the safety of the substation.

In various embodiments the electro-optic crystal assembly 200 includes graded refractive index (GRIN) optics 216 at each longitudinal end of the electro-optic crystal 202, and are configured to facilitate the proper transition of light from and to the end of the optical fiber 208 and the light collector 210, respectively. For example, GRIN optics may help focus the light and/or reduce attenuation.

In illustrative embodiments, the electro-optic crystal 202 together with the electrodes 204, and, optionally, the GRIN optics 216 and, further optionally, the strain relief bushings 214, can form a crystal package, and can be housed in a housing 218, which may be, for example, 3-D printed.

Tests performed with optical voltage sensor systems, using polarized and unpolarized light, reveal that the magnitude of the response is typically dependent on the polarization state of the light passing through the crystal. Tests using a LiNbO3 crystal with the electrode pattern shown in FIG. 3 demonstrated that one polarization classification-linear polarization-exhibits approximately 2.5 times more sensitivity to voltage than the other polarization classifications. However, optical voltage sensor systems according to the present disclosures provide a sufficiently stable overall response through the use of unpolarized light passing through the crystal. That is, the sensitivity in using depolarized light is sufficient to obtain an average sensitivity. The use of unpolarized light results in considerable cost savings by eliminating the need for polarizers and waveplates and reducing the cost of alignment and glue interfaces.

During testing, a 100V AC signal provided approximately 20% intensity modulation of the light at 1.3 μm wavelength. No polarization optics were required in the crystal package. The sensitivity was sufficiently stable with respect to the polarization characteristics of the light source. Furthermore, a flat frequency response with low distortion was measured at least from DC to 1 kHz. Advantageously, the crystal package according to various embodiments of the present disclosure can operate bi-directionally, and thus can allow for independent redundant probing.

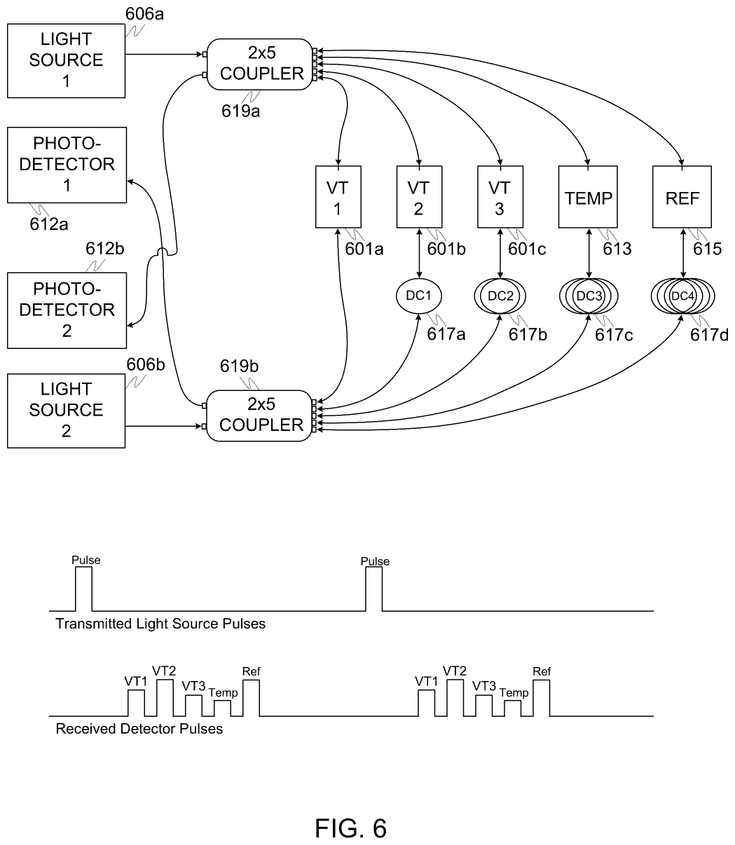

FIG. 6 depicts a schematic representation of an optical voltage sensing device suitable for sensing multiple signals in accordance with various embodiments. The optical voltage sensing device includes a first light source 606a and a second light source 606b, a first photodetector 612a and a second photodetector 612b, first and second 2×5 couplers 619a-b, and first, second and third voltage transducers 601a-c. The optical voltage sensing device also includes a temperature unit 613, a reference unit 615, and delay coils 617a-d.

The first light source 606a provides an unpolarized light pulse to the first 2×5 coupler 619a which divides the light pulse into five pulses, and in turn sends the five light pulses respectively along five paths: to the three voltage transducers 601a, 601b and 601c, and also to the temperature unit 613 and the reference unit 615. Typically, the three voltage transducers 601a-c are configured to sense the amplitudes of the three phases of an electrical transport line. The voltage transducers 601a-c each have a functionality similar to the components of electro-optic crystal assembly 200 contained in box 601 of FIG. 2.

The reference unit 615 may be implemented as a section fiber optic cable that passes the signal pulse straight through, without attenuating or degrading it, to be used as a reference signal for the temperature unit 613. The temperature unit 613 a loss that varies with temperature, and is physically located next to the electro-optic crystal (e.g., electro-optic crystal 202 of FIG. 2). The difference between the pulse amplitude from the temperature unit 613 and the pulse amplitude from the reference unit 615 indicates how much the signal should be compensated based on losses due to temperature.

The first voltage transducer 601a is coupled directly between the first 2×5 coupler 619a—which is connected to the light source 606a and photodetector 612b—and the second 2×5 coupler 619b—which is connected to light source 606b and photodetector 612a. Each of the remaining components—the second and third voltage transducers 601b and 601c, temperature unit 613 and reference unit 615—have one of the delay coils 617a-d coupled in their respective path to the second 2×5 coupler 619b. The delay coils 617a-d each have differing amounts of delay associated with them. The operation of the 2×5 couplers 619a-b taken with the delay coils 617a-d results in time division multiplexing of the pulse from light source 606a.

In FIG. 6, as can be seen by the timing diagram, delay coil 617d has more delay than delay coil 617c, which has more delay than delay coil 617b, which has more delay than delay coil 617a. The delay coils delay coil 617a-d are each coupled to the second 2×5 coupler 619b. Light from the first voltage transducer 601a is coupled to the second 2×5 coupler 619b without any delay coil. The five light pulses sent to the second 2×5 coupler 619b are recombined into a single signal which is sent to photodetector 612a. The timing of the five light pulses, as compared to the initial pulse from light source 606a, can be seen at the bottom of FIG. 6 in the timing diagrams. The pulses labeled 601a, 601b and 601c in the timing diagram of FIG. 6 typically represent the voltages of the three phases of a high-voltage electrical transport line.

The optical voltage sensing device of FIG. 6 operates in a manner similar to the electro-optic crystal assembly of FIG. 2, except the time division multiplexing of the light pulse from light source 606a allows the voltages of all three phases of a HV transport line to be sensed separately. Using a multiplexor ladder assembly such as that depicted in FIG. 6 to sense all three phases cuts the circuitry costs by around 65% as compared to conventional devices.

The optical voltage sensing device of FIG. 6 is bi-directional. That device is able to work using a light pulse from light source 606b, through the second 2×5 coupler 619b to divide the pulse, through the delay components 617a-d and the voltage transducers 601a-c. The first 2×5 coupler 619a then recombines the signals and feeds it into photodetector 612b.

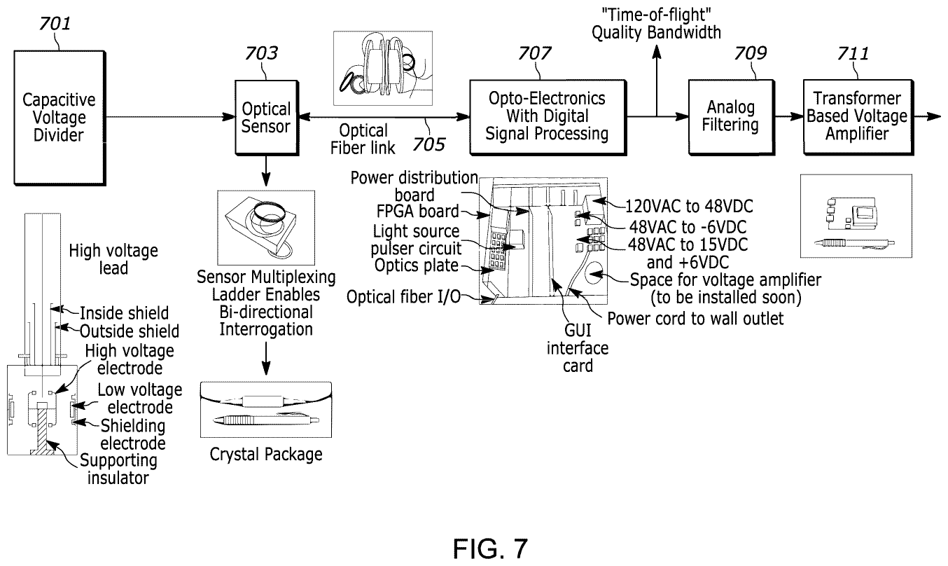

FIG. 7 is a block diagram of the system components including the optical voltage sensing device as a component of the system, according to various embodiments. The system architecture includes a capacitive voltage divider 701 which generates a generate a low-voltage signal representative of the high-voltage signal. Since the sensed signals are sent by fiber optic cable the capacitance of the voltage divider can be much lower than is needed with conventional systems that send sensed electrical signals. This eliminates the need for oil or SF6 in the capacitive voltage divider as is necessary using conventional CVT technology. In some implementations the capacitive voltage divider 701 may be solid state. A presently preferred solid state divider is described in commonly owned and co-pending U.S. Ser. No. 19/068,063, filed Mar. 3, 2025, based on U.S. Provisional Application No. 63/560,207 filed on Mar. 1, 2024, both entitled “High Voltage Solid Insulated Capacitive-Resistive Divider” to Dragan D. Tabakovic, the entire contents of both of which are hereby incorporated by reference.

The capacitive voltage divider 701 feeds the low-voltage signal to optical sensor 703. The optical sensor 703—an optical voltage sensing device—is constructed and operates in the manner in accordance with the various embodiments described in this disclosure. The optical sensor 703 outputs the sensed signals via optical fiber link 705 for further monitoring and processing to the opto-electronics unit 707 with digital signal processing capabilities. The opto-electronics unit 707, in turn, feeds the signal to an analog filtering unit 709 and transformer based voltage amplifier 711.

As will now be appreciated by one of ordinary skill in the art armed with the present specification, the inventors recognized several drawbacks associated with conventional CVT technology. Various embodiments according to the present disclosure provide optical voltage sensing systems, and more particularly to optical voltage sensing systems using unpolarized light passing through an electro-optic crystal assembly. These provide a simple, low-cost solution for converting a primary voltage signal to an intensity-modulated light beam. Various embodiments according to the present disclosure use a low-capacitance (e.g., pico-Farads) voltage divider to reproduce a low-voltage replica of the high voltage to be sensed.

In various embodiments, because the capacitance is much lower than what is conventionally required for CVT technology, oil or SF6 insulation can be omitted. Rather, the capacitive divider can be made to be solid state. In various embodiments, because there is no inductive element in the voltage divider, the system is linear, and thus at low risk of suffering from non-linear magnetic effects. As a result, the system bandwidth can be made flat and smooth over the frequencies of interest, thus solving one of the drawbacks of conventional systems.

In some applications, a low-capacitance voltage divider is particularly advantageous if located near an optical element configured to detect its signal, and if the signal is not electrically loaded. In various embodiments the low-voltage signal is applied directly to an electro-optic crystal which then deflects or contorts a beam of light passing through it in response to the applied voltage. Using an optical fiber affixed to (or near) the crystal as a receiver, the intensity of the light captured in the receiver optical fiber can be made to be linearly dependent on the voltage applied to the crystal.

Advantageously, it can be significantly lower in cost to launch unpolarized light into the crystal than to launch polarized light into the crystal while managing the polarization state. Management of the polarization state could require the use of polarizers and waveplates which add parts, complexity, manufacturing and alignment costs, and potentially undesirable glue interfaces. An unpolarized system can avoid the need for these elements and can thus improve both cost and reliability when compared to a polarized light manipulation system.

One of ordinary skill will appreciate that the exact dimensions and materials are not critical to the disclosure and all suitable variations should be deemed to be within the scope of the disclosure if deemed suitable for carrying out the objects of the disclosure.

One of ordinary skill in the art will also readily appreciate that it is well within the ability of the ordinarily skilled artisan to modify one or more of the constituent parts for carrying out the various embodiments of the disclosure. Once armed with the present specification, routine experimentation is all that is needed to determine adjustments and modifications that will carry out the present disclosure.

The above embodiments are for illustrative purposes and are not intended to limit the scope of the disclosure or the adaptation of the features described herein to particular optical voltage sensing systems or electro-optic crystal assemblies. Those skilled in the art will also appreciate that various adaptations and modifications of the above-described preferred embodiments can be configured without departing from the scope and spirit of the disclosure. Therefore, it is to be understood that, within the scope of the appended claims, the invention may be practiced other than as specifically described.

What is claimed is:

1. An optical voltage sensor system for measuring a high-voltage signal, the optical voltage sensor system comprising:
a voltage divider configured to generate a low-voltage signal representative of the high-voltage signal;
an electro-optic crystal;
a plurality of electrodes arranged on the electro-optic crystal and connected to receive the low-voltage signal from the voltage divider, the plurality of electrodes being configured, in response to an unpolarized light beam being launched through the electro-optic crystal, to apply a voltage of the low-voltage signal to the electro-optic crystal to alter a spatial distribution of a portion of the unpolarized light beam exiting the electro-optic crystal in response to the low-voltage signal;
a light collector configured to collect the unpolarized light beam exiting the electro-optic crystal as collected light, wherein an intensity of the collected light varies based on the applied voltage; and
a light converter configured to convert the collected light into an electronic signal representative of the high-voltage signal.

2. The optical voltage sensor system according to claim 1, wherein the voltage divider includes one or more passive resistors and one or more capacitors.

3. The optical voltage sensor system according to claim 1, wherein the electro-optic crystal includes Y-cut LiNbO₃.

4. The optical voltage sensor system according to claim 1, further comprising an optical fiber for directing the unpolarized light beam to the electro-optic crystal.

5. The optical voltage sensor system according to claim 4, wherein the optical fiber is a single-mode fiber.

6. The optical voltage sensor system according to claim 4, wherein the optical fiber is a multi-mode fiber.

7. The optical voltage sensor system according to claim 1, further comprising a depolarizer configured to create the unpolarized light beam by passing at least partially polarized light through the depolarizer.

8. The optical voltage sensor system according to claim 7, wherein the depolarizer is a Lyot depolarizer.

9. The optical voltage sensor system according to claim 7, wherein the depolarizer is a polarization scrambler.

10. The optical voltage sensor system according to claim 1, wherein the plurality of electrodes are arranged on the electro-optic crystal so as to create a non-zero electric field gradient across a portion of the light beam propagating through the electro-optic crystal in response to the low-voltage signal.

11. The optical voltage sensor system according to claim 1, wherein the light collector is an optical fiber.

12. The optical voltage sensor system according to claim 11, wherein the optical fiber is a single-mode fiber.

13. The optical voltage sensor system according to claim 11, wherein the optical fiber is a multi-mode fiber.

14. The optical voltage sensor system according to claim 1, further comprising an unpolarized light launcher configured to launch the unpolarized light beam through the electro-optic crystal; and
wherein the plurality of electrodes are strip electrodes.

15. The optical voltage sensor system according to claim 1, wherein the plurality of electrodes includes two positive electrodes arranged on opposite first and second sides of the electro-optic crystal, and two negative electrodes arranged on opposite third and fourth sides of the electro-optic crystal.

16. The optical voltage sensor system according to claim 1, wherein the plurality of electrodes includes two pairs of electrodes arranged on opposite first and second sides of the electro-optic crystal, each pair including a positive electrode and a negative electrode.

17. An electro-optic crystal assembly comprising:
an electro-optic crystal including a first end, a second end opposite the first end, and a plurality of sides;
first graded refractive index optics positioned on the first end of the electro-optic crystal;
second graded refractive index optics positioned on the second end of the electro-optic crystal;
a plurality of electrodes arranged on at least two of the plurality of sides of the electro-optic crystal, wherein at least two electrodes among the plurality of electrodes are configured to receive a low-voltage signal;
wherein the plurality of electrodes are configured, in response to an unpolarized light beam being launched into the first end and through the electro-optic crystal, to apply a voltage of the low-voltage signal to the electro-optic crystal to alter a spatial distribution of a portion of the light beam exiting the second end of the electro-optic crystal in response to the low-voltage signal.

18. The electro-optic crystal assembly according to claim 17, wherein the plurality of electrodes includes two positive electrodes arranged on opposite first and second sides of the electro-optic crystal, and two negative electrodes arranged on opposite third and fourth sides of the electro-optic crystal.

19. The electro-optic crystal assembly according to claim 17, wherein the plurality of electrodes includes two pairs of electrodes arranged on opposite first and second sides of the electro-optic crystal, each pair including a positive electrode and a negative electrode.

20. An optical voltage sensor system for monitoring voltage in a three-phase high voltage power system substation comprising:
a voltage divider configured to generate a low-voltage signal representative of the high-voltage signal in each of three phase conductors in a three-phase power transmission system;
an electro-optic crystal;
a plurality of electrodes arranged on the electro-optic crystal and connected to receive the low-voltage signal from the voltage divider for each of the phase conductors,
a multiplexor ladder assembly having a plurality of delay coils for keeping a low-voltage signal of each of the phase conductors separate;
the plurality of electrodes being configured, in response to an unpolarized light beam being launched through the electro-optic crystal, to apply a voltage of the low-voltage signal as an applied voltage to the electro-optic crystal to alter a spatial distribution of a portion of the light beam exiting the electro-optic crystal in response to the low-voltage signal from each of the phase conductors;
a light collector configured to collect light having an intensity which varies based on the applied voltage and delay of a respective one of the plurality of delay coils associated with each of the phase conductors; and
a light converter configured to convert the collected light into an electronic signal representative of the high-voltage signal.
